(19) United States
(12) Patent Application Publication
(10) Pub. No.: US 2025/0324771 A1
(43) Pub. Date: Oct. 16, 2025

(54) MULTIJUNCTION SOLAR CELL STRUCTURE

(71) Applicant: YANGZHOU CHANGELIGHT CO., LTD., Yangzhou (CN)

(72) Inventor: Zhenlong WU, Yangzhou (CN)

(73) Assignee: YANGZHOU CHANGELIGHT CO., LTD., Yangzhou, JS (CN)

(21) Appl. No.: 19/252,950

(22) Filed: Jun. 27, 2025

Related U.S. Application Data
(63) Continuation of application No. PCT/CN2024/124951, filed on Oct. 15, 2024.

(30) Foreign Application Priority Data
Nov. 10, 2023 (CN) 202311501887.8

(51) Int. Cl. H10F 10/172; H10F 77/124; H10F 77/14; H10F 77/50

(52) U.S. Cl. CPC H10F 10/172; H10F 77/1248; H10F 77/146; H10F 77/50

(57) ABSTRACT

The present disclosure provides a MULTIJUNCTION solar cell structure including a substrate and a plurality of subcells stacked on the substrate. The plurality of subcells include an InGaAs subcell, the InGaAs subcell includes an InjGaAs base region and an InjGaAs emitter region disposed in a direction away from the substrate, and a multiple quantum well (MQW) structure disposed between the InjGaAs base region and the InjGaAs emitter region. The InjGaAs base region and the InjGaAs emitter region are respectively doped with a first and second conductivity types. The MQW structure includes alternately stacked InxGaAs quantum well layers and InkGaAsPy barrier layers, and a InwGaAsPz step barrier layer disposed between a InxGaAs quantum well layer and a InkGaAsPy barrier layer. A bandgap of the InwGaAsPz step barrier layer lies between a bandgap of the InxGaAs quantum well layer and a bandgap of the InkGaAsPy barrier layer.

### CROSS-REFERENCE TO RELATED APPLICATIONS

The present application claims priority to PCT Application No. PCT/CN2024/124951, entitled “MULTIJUNCTION SOLAR CELL STRUCTURE” and filed on Oct. 15, 2024, which claims priority to Chinese patent Application No. 202311501887.8, filed with the Chinese Patent Office on Nov. 10, 2023, the entirety of which is incorporated by reference for all purposes.

### BACKGROUND

Solar cells can directly convert solar energy into electrical energy, providing an effective form of clean energy. Traditional solar cells are typically silicon-based, but silicon solar cells have a relatively narrow absorption band in the solar spectrum. Consequently, multijunction solar cells have emerged. These cells are formed by connecting multiple subcells with different bandgaps in series through tunnel junctions. Each subcell absorbs a different spectral band of sunlight, significantly improving the conversion efficiency. III-V compound semiconductor solar cells currently offer the highest conversion efficiency among available material systems. They also have advantages such as excellent high-temperature performance and strong radiation resistance. As a result, they are widely recognized as the next-generation high-performance, long-lifespan primary power sources for space applications. In particular, multijunction solar cells with lattice-matched GaInP/InGaAs/Ge structures have been extensively applied in the aerospace field.

However, conventional lattice-matched multijunction solar cells often experience current density mismatches among the GaInP top cell, InGaAs middle cell, and Ge bottom cell, which limits their photoelectric conversion efficiency. One way to address this issue is by increasing the current density of the subcells. This can be achieved by increasing the indium composition in the InGaAs layer of the middle cell, thereby reducing the bandgaps of the middle and top subcells and increasing their short-circuit currents, improving current matching with the Ge bottom cell and boosting overall efficiency. However, a higher indium composition leads to significant lattice mismatch between the Ge substrate and the InGaAs layer, resulting in misfit dislocations and threading dislocations, which degrade the cell's performance. Another approach involves introducing a multiple quantum well (MQW) structure into the InGaAs middle cell. By introducing intermediate energy levels, the MQW structure extends the spectral response of the middle cell, thereby increasing its short-circuit current. Furthermore, by adjusting the spectral response of the InGaAs middle cell, the matching current between the top and middle cells can be optimized, leading to an improvement in overall conversion efficiency.

Compared with conventional MQW structures that use InGaAs quantum well layers and GaAs barrier layers, strain-balanced MQW structures employ InGaAs quantum well layers and (In)GaAsP barrier layers. However, strain-balanced MQW structures also face several challenges, first, the high potential barriers of the periodic (In)GaAsP layers hinder the transport of photogenerated carriers. While a sufficient number of quantum well periods is critical for carrier collection and solar cell performance, a large number of (In)GaAsP layers significantly obstruct carrier transport, reducing the open-circuit voltage and fill factor; Second, to balance the compressive strain of the InGaAs quantum well layers, the (In)GaAsP barrier layers must provide adequate tensile strain, requiring a certain thickness. However, thicker (In)GaAsP layers are more likely to generate dislocations; Third, the interface between the InGaAs quantum wells and the (In)GaAsP barrier layers consists of AsP, where atomic interdiffusion can occur. This degrades interface flatness and negatively impacts photon absorption in the MQW structure.

### SUMMARY

The present disclosure is related to the technical field of solar cells, and in particular, to a multijunction solar cell structure.

According to a first aspect of the present disclosure, some embodiments provide a multijunction solar cell structure. The multijunction solar cell structure includes a substrate and a plurality of subcells stacked on the substrate, wherein the plurality of subcells comprise an InGaAs subcell, wherein the InGaAs subcell comprises an InjGaAs base region and an InjGaAs emitter region disposed in a direction away from the substrate, and a multiple quantum well (MQW) structure located between the InjGaAs base region and the InjGaAs emitter region, wherein the InjGaAs base region is doped with a first conductivity type, and the InjGaAs emitter region is doped with a second conductivity type, wherein the MQW structure comprises alternately stacked InxGaAs quantum well layers and InkGaAsPy barrier layers, and a InwGaAsPz step barrier layer located between a InxGaAs quantum well layer and a InkGaAsPy barrier layer, wherein a bandgap of the InwGaAsPz step barrier layer lies between a bandgap of the InxGaAs quantum well layer and a bandgap of the InkGaAsPy barrier layer, and wherein j, x, y, k, w, z are numbers greater than or equal to 0.

According to a second aspect of the present disclosure, some embodiments provide a multijunction solar cell structure. The multijunction solar cell structure includes a substrate and a plurality of subcells stacked on the substrate, wherein the plurality of subcells comprise an InGaAs subcell, wherein the InGaAs subcell comprises an InjGaAs base region and an InjGaAs emitter region disposed in a direction away from the substrate, and a multiple quantum well (MQW) structure disposed between the InjGaAs base region and the InjGaAs emitter region, wherein the InjGaAs base region is doped with a first conductivity type, and the InjGaAs emitter region is doped with a second conductivity type, wherein the MQW structure comprises alternately stacked InxGaAs quantum well layers and InkGaAsPy barrier layers, and a InwGaAsPz step barrier layer disposed between a InxGaAs quantum well layer and a InkGaAsPy barrier layer, wherein a lattice constant of the InwGaAsPz step barrier layer is between a lattice constant of the InxGaAs quantum well layer and a lattice constant of the InkGaAsPy barrier layer, and wherein j, x, y, k, w, z are numbers greater than or equal to 0.

### DESCRIPTION OF THE DRAWINGS

In order to more clearly illustrate the technical solutions in the embodiments of the present application or in the related art, the accompanying drawings that are required in the description of the embodiments or existing technologies are briefly introduced below. It is evident that the drawings described below are merely examples of embodiments of the present application.

FIG. 1 is a schematic cross-sectional view of a multijunction solar cell structure provided in an embodiment of the present disclosure.

FIG. 2 is a schematic cross-sectional view of one example of an InGaAs subcell in the multijunction solar cell structure provided in an embodiment of the present disclosure.

FIG. 3 is a schematic cross-sectional view of another example of an InGaAs subcell in the multijunction solar cell structure provided in an embodiment of the present disclosure.

FIG. 4 is a schematic cross-sectional view of yet another example of an InGaAs subcell in the multijunction solar cell structure provided in an embodiment of the present disclosure.

FIG. 5 is a schematic cross-sectional view of another multijunction solar cell structure provided in an embodiment of the present disclosure.

### DETAILED DESCRIPTION OF THE DISCLOSURE

The embodiments of the present disclosure will now be described clearly and completely with reference to the accompanying drawings. It should be understood that the described embodiments are only a portion of all possible embodiments of the present application, and not exhaustive. All other embodiments obtained by those skilled in the art based on the embodiments of the present disclosure without creative efforts shall fall within the scope of protection of the present disclosure.

To facilitate a full understanding of the present disclosure, many specific details are described below. However, the present disclosure may also be implemented in ways different from those described herein. A person skilled in the art may make similar extensions without departing from the spirit of the present disclosure. Therefore, the present disclosure is not limited to the specific embodiments disclosed below.

Furthermore, the present disclosure is described in detail with reference to schematic diagrams. When describing the embodiments of the present disclosure, cross-sectional views of device structures may be locally enlarged and not drawn to scale for the sake of clarity. These schematic diagrams are merely illustrative and should not be construed as limiting the scope of protection of the present disclosure. Additionally, actual implementations should consider three-dimensional dimensions of length, width, and depth.

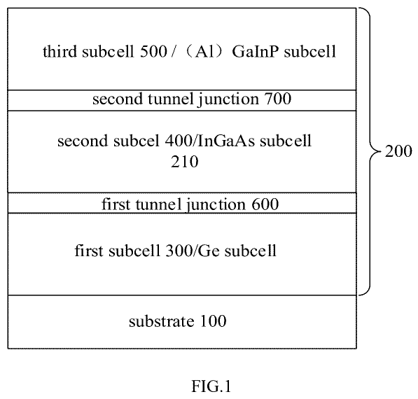

An embodiment of the present disclosure provides a multijunction solar cell structure. FIG. 1 illustrates a schematic cross-sectional view of the multijunction solar cell structure provided by this embodiment. As shown in FIG. 1, the multijunction solar cell structure includes a substrate 100 and multiple subcells 200 stacked on the substrate 100. The multiple subcells 200 include an InGaAs subcell 210.

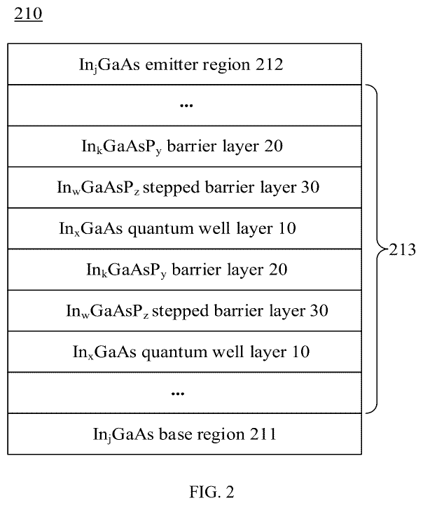

FIG. 2 shows a schematic cross-sectional view of the InGaAs subcell 210 in the multijunction solar cell structure provided by this embodiment. As shown in FIG. 2, the InGaAs subcell 210 includes an InjGaAs base region 211 and an InjGaAs emitter region 212 arranged in a direction away from the substrate 100, and a multiple quantum well (MQW) structure 213 located between the InjGaAs base region 211 and the InjGaAs emitter region 212. The InjGaAs base region 211 is doped with a first conductivity type, and the InjGaAs emitter region 212 is doped with a second conductivity type.

The MQW structure 213 includes alternating layers of InxGaAs quantum well layers 10 and InkGaAsPy barrier layers 20, as well as InwGaAsPz stepped barrier layers 30 located between the InxGaAs quantum well layers 10 and the InkGaAsPy barrier layers 20. The bandgap of the InwGaAsPz stepped barrier layer 30 is between the bandgap of the InxGaAs quantum well layer 10 and that of the InkGaAsPy barrier layer 20. The lattice constant of the InwGaAsPz stepped barrier layer 30 is also between the lattice constants of the InxGaAs quantum well layer 10 and the InkGaAsPy barrier layer 20.

In some embodiments of the present disclosure, the first conductivity type is p-type doping and the second conductivity type is n-type doping. In this case, the InjGaAs base region 211 in the InGaAs subcell 210 is a p-type InjGaAs layer, and the InjGaAs emitter region 212 is an n-type InjGaAs layer. A pn junction is formed at the interface between the InjGaAs base region 211 and the InjGaAs emitter region 212. Majority carriers (holes) in the InjGaAs base region 211 diffuse toward the InjGaAs emitter region 212, leaving behind negatively charged dopant ions, and majority carriers (electrons) in the InjGaAs emitter region 212 diffuse toward the InjGaAs base region 211, leaving behind positively charged dopant ions. This forms a space charge region at the interface, and the built-in electric field of the space charge region points from the InjGaAs emitter region 212 toward the InjGaAs base region 211. As a result, when exposed to light, electron-hole pairs (i.e., photogenerated carriers) are generated. Under the influence of the built-in electric field, photogenerated electrons are transported toward the emitter region 212 and photogenerated holes toward the base region 211, creating a potential difference in the subcell. However, the present disclosure does not limit which of the first or second doping types is p-type or n-type, as long as the types are opposite. Alternatively, the first doping type may be n-type and the second p-type, which is similar and not repeated here.

In the InGaAs subcell 210, specifically between the InjGaAs base region 211 and the InjGaAs emitter region 212, a multiple quantum well structure 213 is arranged. The MQW structure 213 includes alternating InxGaAs quantum well layers 10 and InkGaAsPy barrier layers 20. It is understood that the MQW structure 213 facilitates the collection and transport of photogenerated carriers. In this structure, the lattice constant of the InxGaAs quantum well layer 10 is larger than that of the InjGaAs base region 211, while the lattice constant of the InkGaAsPy barrier layer 20 is smaller than that of the InjGaAs base region 211. Thus, a stress-balanced epitaxial process can be used, in which the compressive stress from the InxGaAs quantum well layers 10 is offset by the tensile stress of the InkGaAsPy barrier layers 20, forming an MQW structure 213 with good lattice quality and stress balance on the InjGaAs base region 211.

However, the MQW structure 213 consisting only of alternating InxGaAs quantum well layers 10 and InkGaAsPy barrier layers 20 in the InGaAs subcell 210 still faces the problems mentioned in the background section. First, the high potential barrier of the periodic InkGaAsPy barrier layers 20 hinders the transport of photogenerated carriers. Furthermore, a sufficient number of MQW periods is essential for effective carrier collection and performance enhancement. A large number of InkGaAsPy barrier layers 20 significantly obstructs carrier transport, reducing the open-circuit voltage and fill factor of the solar cell. Second, to balance the compressive stress from the InxGaAs quantum well layers 10, the InkGaAsPy barrier layers 20 must be thick enough to provide adequate tensile stress. However, excessive thickness may lead to dislocations. Third, the AsP interfaces between the InxGaAs quantum well layers 10 and the InkGaAsPy barrier layers 20 may become uneven due to atomic interdiffusion, negatively impacting the light absorption of the MQW structure 213.

In view of the above, in the multijunction solar cell structure provided in the present disclosure, specifically in the multiple quantum well (MQW) structure 213 of the InGaAs subcell 210, an InwGaAsPz stepped barrier layer 30 is inserted between the InxGaAs quantum well layer 10 and the InkGaAsPy barrier layer 20. The bandgap of the InwGaAsPz stepped barrier layer 30 is set between that of the InxGaAs quantum well layer 10 and the InkGaAsPy barrier layer 20—i.e., the barrier height of the stepped barrier layer 30 is lower than that of the InkGaAsPy barrier layer 20. This facilitates the photogenerated carriers to more easily overcome the barrier of the stepped barrier layer 30, thereby improving carrier transport, enhancing the photoelectric conversion efficiency, and increasing both the open-circuit voltage and the fill factor of the multijunction solar cell. At the same time, the lattice constant of the InwGaAsPz stepped barrier layer 30 is also conFIG.d to lie between the lattice constants of the InxGaAs quantum well layer 10 and the InkGaAsPy barrier layer 20. This allows the InwGaAsPz stepped barrier layer 30 and the InkGaAsPy barrier layer 20 to jointly provide tensile stress to compensate for the compressive stress of the InxGaAs quantum well layer 10, enabling a reduction in the thickness of the InkGaAsPy barrier layer 20 and lowering the risk of dislocations that could occur if the critical thickness is exceeded. Furthermore, to ensure the bandgap of the InwGaAsPz stepped barrier layer 30 is between that of the InxGaAs quantum well layer 10 and the InkGaAsPy barrier layer 20, and that the lattice constant lies in between as well, the P component z in the InwGaAsPz stepped barrier layer 30 can be made smaller than the P component y in the InkGaAsPy barrier layer 20. Compared to the original interface between the InkGaAsPy barrier layer 20 and the InxGaAs quantum well layer 10, the interface between the InwGaAsPz stepped barrier layer 30 and the InxGaAs quantum well layer 10 significantly reduces atomic interdiffusion, yielding a smoother AsP interface and thus enhancing light absorption of the MQW structure 213.

In some embodiments of the present disclosure, a GaAs layer, an InGaAs layer, or an AlInGaAs layer is inserted between the InxGaAs quantum well layer 10 and the InkGaAsPy barrier layer 20 in the MQW structure 213 of the InGaAs subcell 210. Unlike the aforementioned InwGaAsPz stepped barrier layer 30, these GaAs, InGaAs, and AlInGaAs layers function as stepped quantum well layers. It is found that while such insertions can also improve carrier transport, enhance photoelectric conversion efficiency, and raise the open-circuit voltage and fill factor, they do not achieve the same stress-balancing advantages. This is because the lattice constants of the GaAs and InGaAs layers are roughly equivalent to that of the InxGaAs quantum well layer 10, and the AlInGaAs layer has a larger lattice constant. Therefore, inserting these layers cannot reduce the thickness of the InkGaAsPy barrier layer 20. In fact, achieving stress balance may require a thicker InkGaAsPy barrier layer 20, which increases the likelihood of dislocations and negatively impacts the performance of the InGaAs subcell and the overall multijunction solar cell structure.

In an embodiment of the present disclosure, the In content j in the InjGaAs base region 211 and the InjGaAs emitter region 212 is set to zero, making both regions GaAs-based. That is, the InjGaAs base region 211 and emitter region 212 are both GaAs layers with different doping types. To achieve lattice matching, the In content k in the InkGaAsPy barrier layer 20 is set to zero, making it a GaAsP barrier layer, and likewise, the In content w in the InwGaAsPz stepped barrier layer 30 is set to zero, making it a GaAsP stepped barrier layer.

In this embodiment, since both the InkGaAsPy barrier layer 20 and the InwGaAsPz stepped barrier layer 30 are made of GaAsP, and considering that in GaAsP material the bandgap widens and the lattice constant decreases as the P content increases, z is set to be less than y—i.e., the P component z in the GaAsPz stepped barrier layer 30 is smaller than the P component y in the GaAsPy barrier layer 20. This ensures that the bandgap of the GaAsPz stepped barrier layer 30 lies between that of the InxGaAs quantum well layer 10 and the GaAsPy barrier layer 20—i.e., the barrier height of the stepped barrier layer 30 is lower than that of the barrier layer 20—and its lattice constant also lies between those of the InxGaAs quantum well layer 10 and the GaAsPy barrier layer 20.

In some embodiments of the present disclosure, the indium (In) composition in the InjGaAs base region 211 and the InjGaAs emitter region 212 is greater than zero, i.e., InjGaAs base region 211 and InjGaAs emitter region 212 are both InGaAs layers with different doping types. To achieve lattice matching, in the multi-quantum well structure 213, the In composition in the InkGaAsPy barrier layer 20 is also greater than zero, making it an InGaAsP barrier layer. Similarly, the In composition in the InwGaAsPz step barrier layer 30 is also greater than zero, making it an InGaAsP step barrier layer.

In this embodiment, both the InkGaAsPy barrier layer 20 and the InwGaAsPz step barrier layer 30 are made of InGaAsP. In the InGaAsP material, the bandgap and lattice constant can be tuned by adjusting the indium (In) content, the phosphorus (P) content, or both. Therefore, the bandgap and lattice constant of the InwGaAsPz step barrier layer 30 can be set to fall between those of the InxGaAs quantum well layer 10 and the InkGaAsPy barrier layer 20.

In some embodiments of the present disclosure, considering that in InGaAsP materials, when the indium (In) composition is fixed, a higher phosphorus (P) composition leads to a wider bandgap and a smaller lattice constant, therefore, when the In composition w in the InwGaAsPz step barrier layer 30 is equal to the In composition k in the InkGaAsPy barrier layer 20 (i.e., w=k), it is necessary to set z<y, meaning that the phosphorus composition z in the InwGaAsPz step barrier layer 30 is less than the phosphorus composition y in the InkGaAsPy barrier layer 20. This ensures that the bandgap of the InwGaAsPz step barrier layer 30 lies between the bandgaps of the InxGaAs quantum well layer 10 and the InkGaAsPy barrier layer 20, and that the lattice constant of the InwGaAsPz step barrier layer 30 lies between the lattice constants of the InxGaAs quantum well layer 10 and the InkGaAsPy barrier layer 20.

In some embodiments of the present disclosure, considering that in InGaAsP materials, when the phosphorus (P) composition is fixed, increasing the indium (In) composition results in a narrower bandgap and a larger lattice constant. Therefore, when the phosphorus composition z in the InwGaAsPz step barrier layer 30 is equal to the phosphorus composition y in the InkGaAsPy barrier layer 20 (i.e., z=y), it is necessary to set w>k, meaning that the indium composition w in the InwGaAsPz step barrier layer 30 is greater than the indium composition k in the InkGaAsPy barrier layer 20. This configuration ensures that the bandgap of the InwGaAsPz step barrier layer 30 lies between the bandgaps of the InxGaAs quantum well layer 10 and the InkGaAsPy barrier layer 20, and that the lattice constant of the InwGaAsPz step barrier layer 30 lies between the lattice constants of the InxGaAs quantum well layer 10 and the InkGaAsPy barrier layer 20.

As a result, by inserting the InwGaAsPz step barrier layer 30 between the InxGaAs quantum well layer 10 and the InkGaAsPy barrier layer 20, the thickness of the InkGaAsPy layer can be reduced. In some embodiments of the present disclosure, the thickness of the InxGaAs quantum well layer 10 may range from about 1 nm to 20 nm; similarly, the InkGaAsPy barrier layer 20 may range from about 1 nm to 20 nm. This keeps both layers under 20 nm to avoid dislocation due to stress relaxation. The InwGaAsPz step barrier layer 30 may range from about 1 nm to 5 nm, as it acts as an intermediate layer and should not be too thick to avoid degrading carrier confinement in the InxGaAs layer.

In some embodiments, the In composition x in the InxGaAs quantum well layer 10 preferably satisfies 0<x≤0.2, and the In composition y in the InkGaAsPy barrier layer 20 satisfies 0<y≤0.5, to ensure suitable potential wells and barriers that support efficient carrier collection and transport.

In the multijunction solar cell structure provided in the embodiments of the present disclosure, specifically within the InGaAs subcell 210, both the InjGaAs base region 211 and the InjGaAs emitter region 212 are composed of InGaAs layers, and the indium (In) composition in the InGaAs layers of both regions is equal.

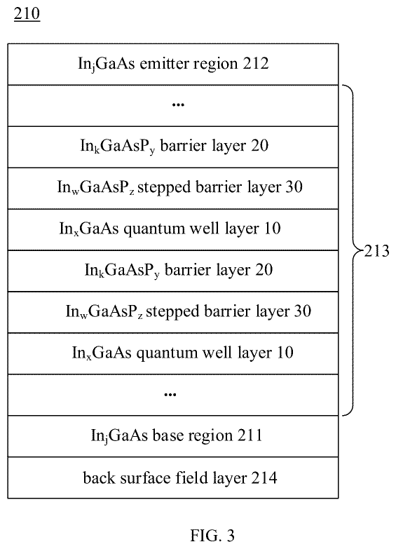

FIG. 3 illustrates a schematic cross-sectional view of another InGaAs subcell in the multijunction solar cell structure provided by the embodiment of the present application. As shown in FIG. 3, in some embodiments of the present disclosure, the InGaAs subcell 210 may further include a back surface field (BSF) layer 214 located on the side of the InjGaAs base region 211 opposite to the InjGaAs emitter region 212. The BSF layer 214 may be an AlInGaAs layer or a GaInP layer, and it is doped with the first conductivity type, meaning that the doping type of the BSF layer 214 is the same as that of the InjGaAs base region 211.

Preferably, the doping concentration of the BSF layer 214 is higher than that of the base region 211. For example, if both are p-type, a p+-p junction is formed, and its built-in electric field aligns with the field of the base-emitter pn junction. This enhances carrier collection and transport, improves photovoltaic conversion efficiency, and boosts operating current and voltage.

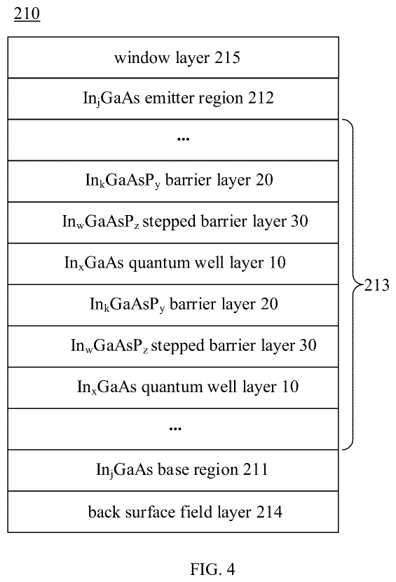

FIG. 4 illustrates a schematic cross-sectional view of yet another InGaAs subcell in the multijunction solar cell structure provided by the embodiment of the present application. As shown in FIG. 4, in some embodiments of the present disclosure, the InGaAs subcell 210 may further include a window layer 215 located on the side of the InjGaAs emitter region 212 opposite to the InjGaAs base region 211. The window layer 215 may be a GaInP layer, an AlGaInP layer, or an AlInP layer, and it is doped with the second conductivity type, meaning that the doping type of the window layer 215 is the same as that of the InjGaAs emitter region 212. In this embodiment, the window layer 215 is connected to the InjGaAs emitter region 212 and can reduce the surface states of the InjGaAs emitter region 212, thereby decreasing surface recombination in the emitter region 212, i.e., lowering the recombination rate of photogenerated carriers at the surface of the emitter, and further enhancing the operating current of the multijunction solar cell.

It should be noted that the present application does not limit the number of subcells included in the multijunction solar cell structure. There may be two, three, or more subcells—i.e., the multijunction solar cell structure may be a dual-junction, triple-junction, or higher-junction solar cell structure—as long as it includes an InGaAs subcell. Accordingly, the InGaAs subcell may comprise an InjGaAs base region 211 and an InjGaAs emitter region 212, as well as a multiple quantum well (MQW) structure 213 located between the InjGaAs base region 211 and the InjGaAs emitter region 212. The MQW structure 213 comprises alternately stacked InxGaAs quantum well layers 10 and InkGaAsPy barrier layers 20, and further includes an InwGaAsPz step-barrier layer 30 inserted between the InxGaAs quantum well layer 10 and the InkGaAsPy barrier layer 20. Additionally, the present application does not specify which particular subcell in the multijunction solar cell structure the InGaAs subcell must be-it may vary depending on the specific configuration.

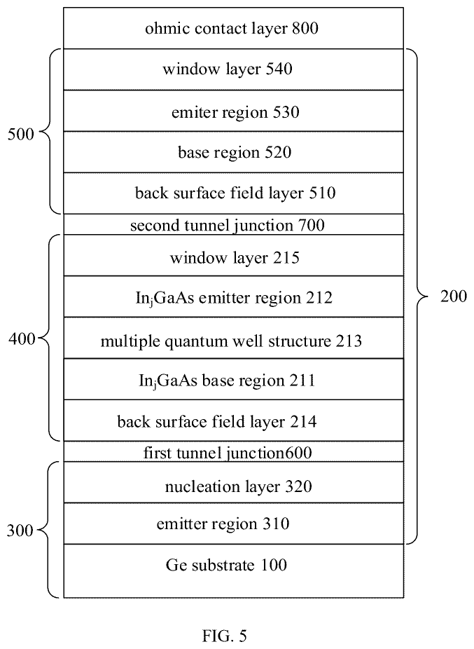

In some embodiments of the present disclosure, the multijunction solar cell structure is a forward triple-junction solar cell structure, as shown in FIGS. 1 and 5. Specifically, in the multijunction solar cell structure, the multiple subcells 200 include a first subcell 300, a second subcell 400, and a third subcell 500 arranged sequentially in a direction away from the substrate 100. The first subcell 300 is a Ge subcell, the second subcell 400 is an InGaAs subcell, and the third subcell 500 is an (Al)GaInP subcell. A first tunnel junction 600 is disposed between the first subcell 300 and the second subcell 400, and a second tunnel junction 700 is disposed between the second subcell 400 and the third subcell 500.

In the specific fabrication process, as shown in FIG. 5, the substrate 100 may be a p-type Ge substrate, which also serves as the base region of the first subcell 300. First, a phosphorus diffusion process is performed on the p-type Ge substrate to form an n-type emitter region 310, thereby forming a pn junction of the first subcell 300. Next, a nucleation layer 320 that is lattice-matched with the Ge substrate is grown on the n-type emitter region 310. This layer also serves as the window layer of the first subcell 300, enhancing reflection of photogenerated carriers and aiding in their collection. In some embodiments of the present disclosure, the nucleation layer 320 may be an (Al)GaInP layer.

Subsequently, a first tunnel junction 600 is grown on the nucleation layer (i.e., the window layer of the first subcell) 320. Specifically, an n-type GaAs layer or n-type GaInP layer may first be grown as the n-type layer of the tunnel junction 600, followed by a p-type (Al)GaAs layer as the p-type layer. The n-type layer of the first tunnel junction 600 may be doped with Si, and the p-type layer may be doped with C.

Next, on the first tunnel junction 600, the following are sequentially grown: a p-type doped back surface field layer 214, a p-type doped InjGaAs base region 211, a multiple quantum well (MQW) structure 213, an n-type doped InjGaAs emitter region 212, and an n-type doped window layer 215—together forming the second subcell 400, i.e., the InGaAs subcell. The back surface field layer 214 may be an AlInGaAs layer or a GaInP layer. The window layer 215 may be a GaInP layer, AlGaInP layer, or AlInP layer. The MQW structure 213 includes alternating InxGaAs quantum well layers 10 and InkGaAsPy barrier layers 20, with an InwGaAsPz step-barrier layer 30 inserted between the InxGaAs and InkGaAsPy layers. The number of MQW periods may range from 1 to 100. Since the structure of the second subcell 400 (InGaAs subcell) has already been described in detail in the preceding embodiments, further explanation is omitted here.

Then, the second tunnel junction 700 is grown on the second subcell 400. Specifically, an n-type GaAs layer or n-type GaInP layer is first grown as the n-type layer of the second tunnel junction 700, followed by a p-type (Al)GaAs layer as the p-type layer. The n-type layer of the second tunnel junction 700 may be doped with Si, and the p-type layer may be doped with C.

After that, the third subcell 500 is formed by sequentially growing: a p-type doped AlGaInP back surface field layer 510, a p-type doped AlGaInP or GaInP base region 520, an n-type doped AlGaInP or GaInP emitter region 530, and an n-type doped AlInP window layer 540.

Finally, an n-type ohmic contact layer 800 made of GaAs or InGaAs is grown on the third subcell 500 to form an ohmic contact with the electrode.

In some embodiments of the present disclosure, letters such as j, x, y, k, w, z represent numbers greater than or equal to 0. The various sections of this specification are described using a combination of parallel and progressive approaches. Each section primarily highlights the differences compared to the others, while similar or identical parts among the sections may be cross-referenced as needed.

The above descriptions of the disclosed embodiments indicate that the features described in the respective embodiments of this specification can be interchanged or combined, enabling those skilled in the art to implement or utilize the present disclosure. Various modifications to these embodiments will be apparent to those skilled in the art, and the general principles defined herein can be applied to other embodiments without departing from the spirit or scope of the present disclosure. Therefore, the present disclosure is not limited to the embodiments described herein but should be accorded the broadest scope consistent with the principles and novel features disclosed.

1. A multijunction solar cell structure, comprising:
a substrate and a plurality of subcells stacked on the substrate, wherein the plurality of subcells comprise an InGaAs subcell,
wherein the InGaAs subcell comprises an InjGaAs base region and an InjGaAs emitter region disposed in a direction away from the substrate, and a multiple quantum well (MQW) structure disposed between the InjGaAs base region and the InjGaAs emitter region, wherein the InjGaAs base region is doped with a first conductivity type, and the InjGaAs emitter region is doped with a second conductivity type,
wherein the MQW structure comprises alternately stacked InxGaAs quantum well layers and InkGaAsPy barrier layers, and a InwGaAsPz step barrier layer disposed between an InxGaAs quantum well layer and an InkGaAsPy barrier layer,
wherein a bandgap of the InwGaAsPz step barrier layer lies between a bandgap of the InxGaAs quantum well layer and a bandgap of the InkGaAsPy barrier layer, and
wherein j, x, y, k, w, z are numbers greater than or equal to 0.

2. The multijunction solar cell structure according to claim 1, wherein a lattice constant of the InwGaAsPz step barrier layer is between a lattice constant of the InxGaAs quantum well layer and a lattice constant of the InkGaAsPy barrier layer.

3. The multijunction solar cell structure according to claim 1, wherein j=0, the InjGaAs base region is a GaAs base region, and the InjGaAs emitter region is a GaAs emitter region, and
in the MQW structure, k=0, the InkGaAsPy barrier layer is a GaAsP barrier layer, w=0, and the InwGaAsPz step barrier layer is a GaAsP step barrier layer, wherein z<y.

4. The multijunction solar cell structure according to claim 1, wherein j>0, the InjGaAs base region is an InGaAs base region, and the InjGaAs emitter region is an InGaAs emitter region, and
in the MQW structure, k>0, the InkGaAsPy barrier layer is an InGaAsP barrier layer, w>0, and the InwGaAsPz step barrier layer is an InGaAsP step barrier layer.

5. The multijunction solar cell structure according to claim 4, wherein w=k, and z<y; or
z=y, and w>k.

6. The multijunction solar cell structure according to claim 1, wherein a thickness of the InxGaAs quantum well layer is in a range of about 1 nm to about 20 nm,
a thickness of the InkGaAsPy barrier layer is in a range of about 1 nm to 20 nm, and
a thickness of the InwGaAsPz step barrier layer is in a range of about 1 nm to 5 nm.

7. The multijunction solar cell structure according to claim 1, wherein 0<x≤0.2 and 0<y≤0.5.

8. The multijunction solar cell structure according to claim 1, wherein the InGaAs subcell further comprises:
a back surface field (BSF) layer disposed on a side of the InjGaAs base region opposite the InjGaAs emitter region, wherein the BSF layer is an AlInGaAs layer or a GaInP layer, and the BSF layer is doped with the first conductivity type.

9. The multijunction solar cell structure according to claim 1, wherein the InGaAs subcell further comprises:
a window layer disposed on a side of the InjGaAs emitter region opposite the InjGaAs base region, wherein the window layer is a GaInP layer, AlGaInP layer, or AlInP layer, and the window layer is doped with the second conductivity type.

10. The multijunction solar cell structure according to claim 1, wherein the plurality of subcells comprise a first subcell, a second subcell, and a third subcell arranged in a direction away from the substrate, wherein the first subcell is a Ge subcell, the second subcell is the InGaAs subcell, and the third subcell is an (Al)GaInP subcell, and
wherein a first tunnel junction is disposed between the first subcell and the second subcell, and a second tunnel junction is disposed between the second subcell and the third subcell.

11. The multijunction solar cell structure according to claim 1, wherein the first conductivity type is p-type doping, and the second conductivity type is n-type doping, or
the first conductivity type is n-type doping, and the second conductivity type is p-type doping.

12. A multijunction solar cell structure, comprising:
a substrate and a plurality of subcells stacked on the substrate, wherein the plurality of subcells comprise an InGaAs subcell,
wherein the InGaAs subcell comprises an InjGaAs base region and an InjGaAs emitter region disposed in a direction away from the substrate, and a multiple quantum well (MQW) structure disposed between the InjGaAs base region and the InjGaAs emitter region, wherein the InjGaAs base region is doped with a first conductivity type, and the InjGaAs emitter region is doped with a second conductivity type,
wherein the MQW structure comprises alternately stacked InxGaAs quantum well layers and InkGaAsPy barrier layers, and a InwGaAsPz step barrier layer disposed between an InxGaAs quantum well layer and an InkGaAsPy barrier layer,
wherein a lattice constant of the InwGaAsPz step barrier layer is between a lattice constant of the InxGaAs quantum well layer and a lattice constant of the InkGaAsPy barrier layer, and wherein j, x, y, k, w, z are numbers greater than or equal to 0.

13. The multijunction solar cell structure according to claim 12, wherein j=0, the InjGaAs base region is a GaAs base region, and the InjGaAs emitter region is a GaAs emitter region, and
in the MQW structure, k=0, the InkGaAsPy barrier layer is a GaAsP barrier layer, w=0, and the InwGaAsPz step barrier layer is a GaAsP step barrier layer, wherein z<y.

14. The multijunction solar cell structure according to claim 12, wherein j>0, the InjGaAs base region is an InGaAs base region, and the InjGaAs emitter region is an InGaAs emitter region, and
in the MQW structure, k>0, the InkGaAsPy barrier layer is an InGaAsP barrier layer, w>0, and the InwGaAsPz step barrier layer is an InGaAsP step barrier layer.

15. The multijunction solar cell structure according to claim 14, wherein w=k, and z<y; or
z=y, and w>k.

16. The multijunction solar cell structure according to claim 12, wherein a thickness of the InxGaAs quantum well layer is in a range of 1 nm to 20 nm, inclusive,
a thickness of the InkGaAsPy barrier layer is in a range of 1 nm to 20 nm, inclusive, and
a thickness of the InwGaAsPz step barrier layer is in a range of 1 nm to 5 nm, inclusive.

17. The multijunction solar cell structure according to claim 12, wherein 0<x≤0.2 and 0<y≤0.5.

18. The multijunction solar cell structure according to claim 12, wherein the InGaAs subcell further comprises:
a back surface field (BSF) layer disposed on a side of the InjGaAs base region opposite the InjGaAs emitter region, wherein the BSF layer is an AlInGaAs layer or a GaInP layer, and the BSF layer is doped with the first conductivity type; or
a window layer disposed on a side of the InjGaAs emitter region opposite the InjGaAs base region, wherein the window layer is a GaInP layer, AlGaInP layer, or AlInP layer, and the window layer is doped with the second conductivity type.

19. The multijunction solar cell structure according to claim 12, wherein the plurality of subcells comprise a first subcell, a second subcell, and a third subcell arranged in a direction away from the substrate, wherein the first subcell is a Ge subcell, the second subcell is the InGaAs subcell, and the third subcell is an (Al)GaInP subcell, and
wherein a first tunnel junction is disposed between the first subcell and the second subcell, and a second tunnel junction is disposed between the second subcell and the third subcell.

20. The multijunction solar cell structure according to claim 12, wherein the first conductivity type is p-type doping, and the second conductivity type is n-type doping, or
the first conductivity type is n-type doping, and the second conductivity type is p-type doping.
